(19) United States
(12) Patent Application Publication
(10) Pub. No.: US 2023/0335671 A1
(43) Pub. Date: Oct. 19, 2023

(54) LIGHT REPLICATION / RETRANSMISSION APPARATUS AND METHOD

(71) Applicant: ams Sensors Singapore Pte. Ltd., Singapore (SG)

(72) Inventors: Francesco Paolo D'Aleo, Eindhoven (NL); Peter Roentgen, Eindhoven (NL); Nicola Spring, Eindhoven (NL); Kotaro Ishizaki, Eindhoven (NL)

(73) Assignee: ams Sensors Singapore Pte. Ltd., Singapore (SG)

(21) Appl. No.: 18/042,653

(22) PCT Filed: Jul. 6, 2021
(86) PCT No.: PCT/SG2021/050389

§ 371 Date: Feb. 23, 2023

(30) Foreign Application Priority Data
Aug. 27, 2020 (GB) 2013414.4

(51) Int. Cl. H01L 33/10; H01L 33/44; H01L 25/16; H01L 33/26; H01L 33/00

(52) U.S. Cl. CPC H01L 33/10; H01L 33/44; H01L 25/167; H01L 33/26; H01L 33/0008

(57) ABSTRACT

A substantially planar light replication or re-transmission component having an incident light receiving surface and an opposed light emitting surface. The component comprises a substantially transparent planar substrate, one or more bipolar junction transistors provided on said substrate, the or each transistor comprising a collector region adjacent to said light receiving surface, an emitter region adjacent to said light emitting surface, and a base region between said collector region and said emitter region, and circuitry for biasing the bipolar transistors in use. The or each transistor is configured and biased in use so that said collector and base regions of the transistor operate as a photodiode whilst said base and emitter regions operate as a light emitting diode.

### TECHNICAL FIELD

The present invention relates to a light replication or retransmission apparatus and method in particular to such an apparatus and method that utilises light emitting transistors.

### BACKGROUND

There exists a number of applications in which it is desirable or even necessary to provide a component that is able to receive directed light at an input surface and provide corresponding light at an output surface, with the light at the output surface being essentially Lambertian, i.e. the radiance of light emitted towards an observer is independent of the observation direction. Such a component may be desirable where the light originates from a Lambertian emitter, e.g. a real-world environment, and is pre-processed such that the light becomes directional, and it is necessary to restore the light to its essentially original omni-directional form. This is further illustrated in FIG. 1, where the component that transforms the direction light into omni-directional light is identified by reference numeral 1.

One set of solutions make use of fluorescent or phosphorescent films, where the input directional light excites the films causing them to emit omni-directional light. Such solutions are relatively simple but are likely to operate only at very restricted wavelengths. They will also be extremely lossy, with the energy of the emitted light being only a fraction of the energy of the input light.

Alternative solutions might make use of a matrix of integrated photodiodes on an input side of the component and an array of light emitting diodes (LEDs) on an output side. The photodiodes may be replaced with photo-transistors whilst the LEDs may be replaced with light emitting transistors. Such components would likely require complex interconnections plus amplification circuits.

U.S. Pat. No. 7,067,853 describes a semiconductor-based image intensifier chip and its constituent photodetector array device based in sidewall-passivated mesa hetero-junction phototransistors.

U.S. Pat. No. 9,455,374 describes an integrated hybrid crystal Light Emitting Dioee (LED) display device that may emit red, green, and blue colours on a single wafer.

### SUMMARY

According to the present invention there is provided a substantially planar light replication or re-transmission component having an incident light receiving surface and an opposed light emitting surface. The component comprises a substantially transparent planar substrate, one or more bipolar junction transistors provided on said substrate, the or each transistor comprising a collector region adjacent to said light receiving surface, an emitter region adjacent to said light emitting surface, and a base region between said collector region and said emitter region, and circuitry for biasing the bipolar transistors in use. The or each transistor is configured and biased in use so that said collector and base regions of the transistor operate as a photodiode whilst said base and emitter regions operate as a light emitting diode.

It will be readily appreciated that the component of the invention essentially enables directional light incident on said light receiving surface to be re-emitted from said light emitting surface as omni-directional light. Such a component may preserve the frequency characteristics of the incident light or may transform those characteristics. In this way the component essentially operates as a Lambertian light emitter.

Embodiments of the invention may be configured such that the or each transistor is able, in use, to amplify the intensity of the emitted light relative to the incident light.

The component may comprise a plurality of said bipolar junction transistors arranged as a two dimensional array across said planar substrate. The plurality of bipolar transistors may each be provided as elevated discrete structures on said planar substrate. A passivation layer may be provided on sidewalls of the or each elevated discrete structure.

The collector region may be disposed adjacent to said planar substrate and the planar substrate provides said incident light receiving surface.

One or both of said light receiving surface and said light emitting surface may comprise an anti-reflection coating.

The component may comprise a Bragg reflector having the same doping type as the emitter region disposed between the emitter region and the base region. The Bragg reflector may be provided by a plurality of layers having alternating doping concentrations.

The transparent planar substrate may comprise sapphire.

The or each transistor may be gallium-arsenide or indium-phosphide devices.

The base region may be a floating base.

The component may comprise an electrical contact layer connected to said base region such that an additional light signal can be modulated onto the light emitting surface.

The or each bipolar junction transistor may have an npn or pnp configurations.

### BRIEF DESCRIPTION OF THE DRAWINGS

FIG. 1 illustrates schematically a generally planar light replication/retransmission component having an incident light receiving surface and an opposed light emitting surface;

FIG. 2 illustrates schematically a first embodiment of a light replication/retransmission component based upon a bipolar junction transistor; and

FIG. 3 illustrates schematically a second embodiment of a light replication/retransmission component based upon a bipolar junction transistor.

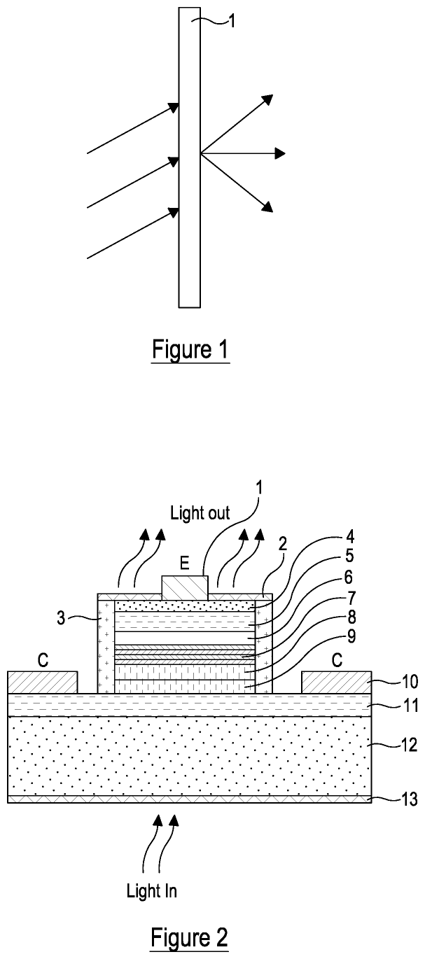

### DETAILED DESCRIPTION

Devices exist, for example Light Emitting Transistors (2004 Holonyak, Feng), which convert electrical current injected to the transistor base into light, when the electrons recombine in the emitter zone in a Light Emitting Diode fashion. Also, organic light emitting transistors (OLET) were introduced back in 2014 using organic materials. Laser transistors (LT) are also known. Whilst an “all-optical transistor based on frustrated total internal reflection” (A. Goodarzi & M. Ghanaatshoar) was introduced in 2018, this does not use a real transistor, only the switch/amplifier concept of the well-known electrical device.

It is well known that in an active zone, bipolar junction transistors (BJTs) work with the base-emitter junction (BEJ) forward biased and the base-collector junction (BCJ) reverse biased. It is proposed here to use this mode of operation to exploit an intrinsic photodiode at the BCJ to detect incoming light whilst re-emitting light from the BEJ which works as an LED, making use of the current gain typical of a BJT. The base and emitter together provide a directly polarized LED.

From the following exemplary embodiments it will be appreciated that in order to provide for an incident light receiving surface and an opposed light emitting surface such as are required for a light replication component, the devices are configured such that their collectors extend across or adjacent to the light input surface, with their emitters extending across the light emitting surface. The bases lie in a plane between the collectors and the emitters.

Whilst the embodiments described below comprise only a single device, it will be appreciated that a practical implementation will likely include a multiplicity (e.g. a two-dimensional array) of devices formed on a common substrate.

It will be further appreciated that a component may require further layers to provide structural support and to accommodate further components including conductive interconnects. All or parts of these components may be provided by transparent or semi-transparent materials such as silicon oxide, silicon nitride, and indium tin oxide.

Embodiments may provide a number of advantage over known light replication components including faster Image reconstruction, simplified component structure, lower cost, and reduced energy consumption.

Embodiments may be used to provide, for example, compact image intensifiers.

Embodiments may be configured, by changing the doping of the three zones, to allow for detection of light at certain wavelength or wavelength range and emit light at different wavelength or wavelength range (double-heterojunctions transistors).

Returning to the proposal for to accomplish the task of replicating or intensifying the incoming photons, FIG. 2 illustrates schematically a first embodiment comprising an n-p-n transistor structure, where the following layers are present:

TABLE 1

| Layer | Reference numeral |
|---|---|
| Transparent Metal (Emitter Contact) | 1 |
| Antireflection Coating | 2 |
| Passivation Layer | 3 |
| N-Type Ohmic Contact | 4 |
| N-Type Semiconductor (Emitter) | 5 |
| N-Type low doped | 6 |
| N-Type Bragg Reflector | 7 |
| P-Type Semiconductor (Base) | 8 |
| P-Type Semiconductor (Absorber) | 9 |
| Transparent Metal (Collector Contact) | 10 |
| N-Type (Collector) | 11 |
| Trigonal c-plane Sapphire | 12 |
| Antireflection Coating | 13 |

The illustrated structure is not planar, as previous attempts to produce such device matrices with no mesas or isolation trenches have suffered from high levels of crosstalk over lateral distances due to carrier diffusion. This crosstalk “smears” or spreads out the incoming image, when the device is organized in a matrix form. A consequence to having elevated structures is the change of energy levels at the border of the pillars. Depending on the semiconductor used this will have different consequences. For example, in the case of gallium-arsenide (GaAs) devices, such a structure pins the Fermi level within the bandgap and will create transistors with reduced gain. In the case of indium-phosphide (InP) devices, the Fermi level will fall within the conduction band leading to higher dark current noise, degrading the photo detecting performances. A solution proposed in the prior art is to passivate the sidewalls with alumina (Al₂O₃), aluminum-nitride (AlN), silicon-nitride (Si₂N₄), silica (SiO₂) or any other electrically insulating inorganic passivating material as shown in FIG. 2.

Antireflection coatings are deposited both on the input surface of the heterojunction structure and on the output surface of the emitters, in order to improve the light collection and emission performance.

One of the critical components of the semiconductor image intensifiers described previously (e.g. U.S. P at. No. 7,067,853) is an optical isolation layer. In such devices the emitting part (led arrays) is required to be optically separated from the photo detecting section (phototransistor arrays) in order to prevent positive feedback (the light emitted re-enters into the base and is amplified again), which can result in an undesirable strong non-linearity in transfer function (from input to output) of the image intensifier. Having a high quality defect-free mesa structure as illustrated in FIG. 2 may increase this feedback, causing performance to deteriorate. Past devices have addressed this problem by introducing a certain level of defects, specifically by changing the mesa formation processing (plasma treatment) to suppress such a feedback but inevitably increasing the dark currents. Other solutions have adopted a high quality mesa, resulting in high positive feedback but using optical insulating layers. Here, and as illustrated in FIG. 2, the emitting part and photo detecting section are integrated, therefore is not possible to introduce optical insulating layers such as metals (thick gold layers) and light absorbing polymers. The solution proposed here is the insertion of a Bragg-reflector, largely used in VCSEL cavities. The Bragg-reflector is a structure formed with the same semiconductor type as the emitter region but with, for example, alternating doping concentrations, to provide a varying refractive index. Alternatively, the Bragg-reflector may have some other periodic variation of a characteristic (such as height) of a dielectric, resulting in periodic variation in the effective refractive index in the region. Each layer boundary causes a partial reflection of an optical wave that travels back to the emitter, hence, blocking the positive feedback.

A clear advantage of the structures proposed here is that, compared to known solutions, no alignment is required between emitting and photo detecting section. In past solutions, these parts were separated and connected by flip-chip arrangement.

The thickness and alloys of the intrinsic or low-doped layers such as the base, base-absorbers, and emitter-base, may be selected such that the narrowest relative bandgap energy may be at the intrinsic or low-doped layer emitting/absorbing red photons. In different wavelength range devices, these zones may be selected to emit/absorb blue photons. If the thickness and the alloy of intrinsic or low-doped layers are critically controlled, a quantum well with discrete energy levels inside the layer may be formed. This may enhance the light emission/detection efficiency.

One embodiment may employ as a substrate material GaAs, for GaAs based devices. In such a case, the substrate thickness must be thinned to several microns, much lower than the carrier diffusion length, in order to improve the quantum efficiency. This is because GaAs is not transparent to visible light (assuming that the device is intended to be sensitive to this wavelength range).

Other embodiments may use trigonal sapphire as a substrate and grow epitaxially III-V and II-VI semiconductor groups (e.g. AlGaInP or AlGalnAs) on the substrate, the epitaxially grown materials having a cubic-rhombohedral zinc-blended structure. Alternatively a hexagonal wurtzite III-Nitride compound semiconductor may be formed. The c-plane sapphire media may be a bulk single crystalline c-plane wafer, a thin free standing sapphire layer, or crack-and-bonded c-plane sapphire layer on any suitable substrate.

In the case of the npn type device of FIG. 2, the base is not connected to the external environment but is rather left floating. Such a floating base simplifies the device structure and eases the thermal “budget”. However, it also places stringent requirements on small-signal gain at zero bias current, which is determined mainly by epitaxial growth quality and by sidewall passivation.

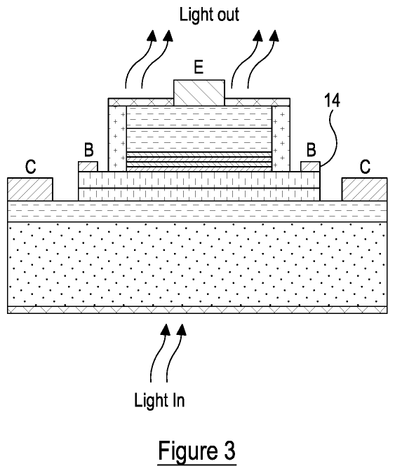

FIG. 3 illustrates schematically an alternative npn configuration in FIG. 2 in which the base electrode is externally reachable in order to add information to the light output, for example for augmented reality application, in which not only the external images needs to be visualized but also additional information. The device of FIG. 3 is in principle similar to that of FIG. 2 (although various layers are omitted for clarity), but with the P-Type Semiconductor (Base) and P-Type Semiconductor (Absorber) layers extended laterally to accommodate a base contact 14.

It will be appreciated by those of skill in the art that various modifications may be made to the above described embodiments without departing from the scope of the present invention. For example, whilst the embodiments above are described in the context of npn devices, it is equally possible that pnp devices can be used.

1. A substantially planar light replication or re-transmission component having an incident light receiving surface and an opposed light emitting surface, the component comprising:
a substantially transparent planar substrate;
one or more bipolar junction transistors provided on said substrate, the or each transistor comprising a collector region adjacent to said light receiving surface, an emitter region adjacent to said light emitting surface, and a base region between said collector region and said emitter region; and
circuitry for biasing the bipolar transistors in use, wherein the or each transistor is configured and biased in use so that said collector and base regions of the transistor operate as a photodiode whilst said base and emitter regions operate as a light emitting diode.

2. A component according to claim 1, wherein the or each transistor is configured and biased so as to amplify the intensity of the emitted light relative to the incident light.

3. A component according to claim 1 and comprising a plurality of said bipolar junction transistors arranged as a two dimensional array across said planar substrate.

4. A component according to claim 3, wherein said plurality of bipolar transistors are each provided as elevated discrete structures on said planar substrate.

5. A component according to claim 4 and comprising a passivation layer on sidewalls of the elevated discrete structures.

6. A component according to claim 1, wherein said collector region is disposed adjacent to said planar substrate and the planar substrate provides said incident light receiving surface.

7. A component according to claim 1, one or both of said light receiving surface and said light emitting surface comprising an anti-reflection coating.

8. A component according to claim 1 and comprising a Bragg reflector having the same doping type as the emitter region disposed between the emitter region and the base region.

9. A component according to claim 8, wherein said Bragg reflector is provided by a plurality of layers having alternating doping concentrations.

10. A component according to claim 1, wherein said transparent planar substrate comprises sapphire.

11. A component according to claim 1, wherein said transistors are gallium-arsenide or indium-phosphide devices.

12. A component according to claim 1, in use, said base region is a floating base.

13. A component according to claim 1 and comprising an electrical contact layer connected to said base region such that an additional light signal can be modulated onto the light emitting surface.
